(19) United States
(12) Patent Application Publication
(10) Pub. No.: US 2025/0044385 A1
(43) Pub. Date: Feb. 6, 2025

(54) SYSTEM AND METHOD FOR STATIC AND DYNAMIC MRI SHIMMING

(71) Applicant: Resonance Research, Inc., Billerica, MA (US)

(72) Inventors: Hoby P. Hetherington, Columbia, MO (US); Piotr M. Starewicz, Lexington, MA (US)

(73) Assignee: Resonance Research, Inc., Billerica, MA (US)

(21) Appl. No.: 18/697,283

(22) PCT Filed: Oct. 4, 2022
(86) PCT No.: PCT/US2022/045670

§ 371 Date: Mar. 29, 2024

Related U.S. Application Data
(60) Provisional application No. 63/251,850, filed on Oct. 4, 2021.

(51) Int. Cl. G01R 33/3875

(52) U.S. Cl. CPC G01R 33/3875

(57) ABSTRACT

A system and method for shimming an MRI system includes a plurality of shim coils distributed around a bore of the MRI system, the shim coils distributed around the bore so that applying an amount of current associated with each coil of the plurality of coils produces a desired magnetic field, wherein the magnetic field is expressed as a set of spherical harmonic terms, each spherical harmonic term having an order. The amount of current associated with at least one coil is different from the amount of current associated with another coil, and at least one coil of the plurality of coils is configured to contribute to a plurality of spherical harmonic terms having different orders.

### CROSS-REFERENCE TO RELATED APPLICATIONS

This application claims priority from U.S. Provisional Patent Application 63/251,850, filed Oct. 4, 2021, which is hereby incorporated herein by reference in its entirety.

### TECHNICAL FIELD

The present invention relates to Nuclear Magnetic Resonance (NMR) and Magnetic Resonance Imaging (MRI), and more particularly to a system and method to shim an MRI system.

### BACKGROUND ART

Nuclear Magnetic Resonance (NMR) and Magnetic Resonance Imaging (MRI) utilize strong magnets to generate a homogeneous magnetic field (B₀) across objects ranging from small sample tubes to the human body. Although the magnets used are very homogeneous, small imperfections in the magnet result in spatial variations in magnetic field strength on the order of parts per million. Additionally, the field becomes even more inhomogeneous when the object (e.g. sample tubes or people) are inserted into them. For example, for the human head, the interfaces between air (e.g. sinuses), bone (skull) and the soft tissue (brain) distort the magnetic field locally and lead to variations (i.e. inhomogeneity) in the B₀ field strength across the object. Since the measured frequency from a specific location varies linearly with B₀ strength at that location, a range in frequencies will be detected across the object. This results in unwanted broadening of the signals from the sample, thereby lowering the signal to noise ratio. Additionally, in MRI, this inhomogeneity also results in geometric distortions (stretching/compression) in the shape of the object being imaged.

To overcome these effects, passive iron shims or active B₀ correction coils, also known as B₀ shims or simply “shims” may be incorporated into the hardware used within the bore of the magnet. Active shims are designed such that each coil generates a unique spatial variation in B₀ field, with its overall strength and sign determined by the amount of current applied to the individual coils. When applied to the object, these coils provide small B₀ correction fields; either increasing or decreasing the local B₀ field strength, so as to make the B₀ field across the object more spatially homogeneous. Thus, when the correct set of currents are applied to the individual active shims, the shims generate a spatially varying B₀ field distribution matching, but opposite in sign, to the distortions generated by the object and any residual imperfections in the magnet.

Placement of the shims and/or adjustment of the current applied to the active shims is optimally achieved by first accurately characterizing the spatial variation in B₀ field across the object by mapping the B₀ field. Once this has been accomplished, the amount of current used to drive each of the shim coils can be calculated using calibrated images of the specific B₀ fields generated by the individual shim coils. However, a complex magnetic field term, or a linear combination of a plurality of magnetic field terms, may be required to compensate the B₀ inhomogeneities. As the available physical space within and around the bore is very limited, an arrangement of coils and method for driving those coils is needed that maximizes the number and complexity of field corrections that can be applied while at the same time minimizing the number of shim coils required to achieve those B₀ field corrections.

### SUMMARY OF THE EMBODIMENTS

The system and methods of the various embodiments of the invention described below achieve highly configurable active shimming with varying shim currents for active shims for the purpose of reducing inhomogeneity when using Magnetic Resonance Imaging (MRI) systems. While the below described embodiments refer to MRI systems, it is to be understood that the invention is applicable to other imaging and spectroscopy systems known in the art, such as, without limitation, Nuclear Magnetic Resonance (NMR) systems

In accordance with one embodiment of the invention, a method of shimming an MRI system is presented. The MRI system has a volume of interest, typically a bore of a superconducting magnet, and a plurality of coils positioned around the bore. The plurality of coils form a shim coil matrix. The method includes determining an amount of current associated with each coil of the plurality of coils, so as to obtain a desired magnetic field, wherein the desired magnetic field is expressed as a set of spherical harmonic terms, each spherical harmonic term having an order. The method further includes simultaneously providing each coil of the plurality of coils its associated amount of current, wherein at least one coil of the plurality of coils is configured to contribute to a plurality of spherical harmonic terms having different orders.

Alternatively or in addition, each spherical harmonic term has an order selected from the group consisting of 1, 2, 3, 4, 5 and 6. Also alternatively or in addition, the amount of current associated with at least one coil is non-zero.

In accordance with another embodiment of the invention, an MRI shim coil system is provided. The system includes a plurality of shim coils distributed around a bore of an MRI system, the shim coils distributed around the bore so that applying an amount of current associated with each coil of the plurality of coils produces a desired magnetic field, wherein the magnetic field is expressed as a set of spherical harmonic terms, each spherical harmonic term having an order. The amount of current associated with at least one coil is different from the amount of current associated with another coil, and at least one coil of the plurality of coils is configured to contribute to a plurality of spherical harmonic terms having different orders.

Alternatively or in addition, each spherical harmonic term has an order selected from the group consisting of 1, 2, 3, 4, 5 and 6. Also alternatively or in addition, the amount of current associated with at least one coil is non-zero.

Further alternatively or in addition, each one of the plurality of coils includes a set of arc portions, and at least one arc portion of at least one coil is arranged so that it partially overlaps with an arc portion of another coil.

Alternatively or in addition, the plurality of coils includes 24 coils and integer multiples thereof. Also alternatively or in addition, each coil of the plurality of coils is substantially rectangular in shape. Further alternatively or in addition, the plurality of coils includes 48 coils arranged in four layers.

In accordance with yet another embodiment of the invention, an MRI shim coil system is provided. The system includes a plurality of shim coils distributed around a bore of an MRI system and a controller, electrically coupled to the plurality of shim coils. The controller is configured to determine an amount of current associated with each coil of the plurality of coils, so as to obtain a desired magnetic field, wherein the desired magnetic field is expressed as a set of spherical harmonic terms, each spherical harmonic term having an order. The controller is also configured to simultaneously provide each coil of the plurality of coils its associated amount of current, wherein at least one coil of the plurality of coils is configured to contribute to a plurality of spherical harmonic terms having different orders.

Alternatively or in addition, each spherical harmonic term has an order selected from the group consisting of 1, 2, 3, 4, 5 and 6. Also alternatively or in addition, the amount of current associated with at least one coil is non-zero.

Further alternatively or in addition, each one of the plurality of coils includes a set of arc portions, and at least one arc portion of at least one coil is arranged so that it partially overlaps with an arc portion of another coil.

Alternatively or in addition, the plurality of coils includes 24 coils and integer multiples thereof. Also alternatively or in addition, each coil of the plurality of coils is substantially rectangular in shape. Further alternatively or in addition, the plurality of coils includes 48 coils arranged in four layers.

### BRIEF DESCRIPTION OF THE DRAWINGS

The foregoing features of embodiments will be more readily understood by reference to the following detailed description, taken with reference to the accompanying drawings, in which:

FIG. 1A shows B₀ maps acquired with static 1^{st} & 2^{nd} degree shims; FIG. 1B shows B₀ maps acquired with static 1^{st}-4^{th+} degree shims; FIG. 1C shows B₀ maps acquired with dynamically updated slice-by-slice with 1^{st}-4^{th+} degree shims; FIG. 1D shows the B₀ map of FIG. 1C with a scale of +/−10 Hz and inverted sign; FIG. 1E shows a plot of standard deviation of each slice of FIGS. 1A, 1B, and 1C; FIG. 1F shows slice #43 from FIG. 1D;

FIG. 2A shows B₀ maps of 58 2 mm slices acquired using static 1 st-4th+shims;

FIG. 2B shows B₀ maps of 58 2 mm slices acquired using 1^{st}-4th+dynamic MB=2 shimming;

FIG. 2C shows MB=2, DSU maps; FIG. 2D shows a single slice map;

FIG. 3A shows a photograph of an exemplary C6/S6 two band head shim insert in accordance with various embodiments of the invention; FIG. 3B shows B₀ maps of a single channel; FIG. 3C shows a B₀ map with currents adjusted to all 48 channels to produce a C2 symmetry; FIG. 3D is a single slice B₀ map of C2 symmetry; FIG. 3E shows B₀ maps of all 48 channels driven to generate a C3 symmetry rotated by 15 degrees; FIG. 3F shows B₀ maps of all 48 channels driven to generate a C6 symmetry;

FIG. 4A shows an exemplary shim coil insert in accordance with various embodiments of the invention;

FIG. 4B shows a cross-sectional view the exemplary shim coil insert;

FIGS. 4C, 4D and 4E illustrate exemplary arrangements of the plurality of coils of the shim coil insert in accordance with various embodiments of the invention;

FIG. 5 shows an exemplary coil in accordance with various embodiments of the invention;

FIG. 6 shows how adjusting the current in individual coils creates the required degree of complexity in any of the harmonic orders in accordance with various embodiments of the invention;

FIG. 7 shows an example of how to combine the currents in a given set of circuits to achieve a desired symmetry in accordance with various embodiments of the invention;

FIG. 8 is a block diagram of an exemplary system for dynamic MRI shimming in accordance with various embodiments of the invention; and

FIG. 9 is a flowchart of an exemplary method for dynamic MRI shimming in accordance with various embodiments of the invention.

### DETAILED DESCRIPTION OF SPECIFIC EMBODIMENTS

Definitions. As used in this description and the accompanying claims, the following terms shall have the meanings indicated, unless the context otherwise requires:

A “set” includes at least one member.

### Spherical Harmonics, Multi-coil Designs and Static Shimming

Conventionally, magnetic resonance (MR) shims are designed to generate field shapes corresponding to the set of orthogonal functions known as spherical harmonics (SH), which are solutions in spherical coordinates to Laplace's equation. This concept is illustrated further in U.S. Pat. Nos. 4,862,087 and 4,949,043 to Hillenbrand et al., both of which are incorporated herein by reference in their entirety. Each spherical harmonic consists of the product of a field term and a source term. The field term provides the spatial variation of that harmonic, and the source term defines its strength. The field term consists of the product of an associated Legendre function, a circular function, and the power of a polar radius. Explicitly, the axial components, i.e. the components in Z direction, of magnetic flux density can be written as follows:

$$B z = - {\sum }_{m = 0}^{∞} {\sum }_{n = m + 1}^{∞} ( {A}_{n}^{m} cos m ϕ + {B}_{n}^{m} sin m ϕ ) {r}^{n - 1} ( n + m ) {P}_{n - 1}^{m} ( u ) \qquad ( Eq . 1 )$$

In Equation 1, u=cos θ and r, θ and φ are the spherical coordinates of the field point. Aₙ^{m} and Bₙ^{m} are the source terms representing the strengths of the spherical harmonics, with n being the degree (maximal radial dependence) and m the order (azimuthal dependence). Thus, the spherical harmonics form an infinite set of polynomials that span all the possible magnetic fields present within any coils inserted in the magnet bore, a consequence of the Laplace theorem. Although the spherical harmonics have some practical drawbacks, they also have the appealing characteristic of being a convenient solution to the magnetic field in free space. (See Hillenbrand D F, Lo K-M, Punchard W F B, Reese T G, Starewicz P M. High-Order MR Shimming: A Simulation Study of the Effectiveness of Competing Methods, Using an Established Susceptibility Model of the Human Head, Applied Magnetic Resonance. 2005; 29:39-64, which is incorporated herein by reference in its entirety).

### Spherical Harmonics, Multi-coil Arrays and Dynamic Shimming

Although both SH and multi-coil (MC) arrays can achieve significant gains in B₀ homogeneity over that of conventional 1^{st} & 2^{nd} order shimming, for the human brain, substantial inhomogeneities remain from inferior brain locations. The need to optimize a single set of harmonics or MC fields over the entire brain is limited by the natural spatial complexity of the brain vs. that of the available correction system (i.e. highest available degree/order for SH shims), or by the numbers and physical arrangement of coils for MC approaches. However, for imaging sequences using multiple slice methods, the achievable B₀ homogeneity can be substantially improved through the use of a series of shim values which are optimized on a slice-by-slice basis through dynamic shim updating (DSU). Recently, it has been demonstrated that the solution space for SH shims is relatively soft, i.e. that constrained optimization of the absolute change in shim current per slice (or, more simply, the aggregate shim current), can dramatically reduce or virtually eliminate eddy current effects with minimal degradation in achieved homogeneity. (See Moon C H, Schwerter M, Pan J, Shah N J, Hetherington H. Constrained Optimization for Static and Dynamic B0 Shimming. ISMRM 2018, #840; and Schwerter M, Hetherington H, Moon C H, Pan J, Felder J, Tellmann L, Shah NJ. Interslice current change constrained B0 shim optimization for accurate high-order dynamic shim updating with strongly reduced eddy currents, Magn Reson Med. 2019 July; 82 (1): 263-275, both of which are incorporated herein in their eintirety). To date, 4^{th} order SHs are either equivalent to or superior to the MC approaches.

### Dynamic B₀ Shimming for Simultaneous Multi-Slice Imaging

Regardless of hardware configuration for shimming, the near universal adoption of simultaneous multi-slice (SMS) or multi-band (MB) imaging for functional MRI (fMRI), including resting state functional MRI (rsfMRI), and diffusion tensor imaging (DTI) and its advantages have made slice-by-slice shimming, even with enhanced B₀ homogeneity, less attractive. Instead, simultaneous multi-slice shimming is achievable with multi-band (MB) factors of 2, approximating that achievable with slice-by-slice shimming. (See Hetherington H, Moon CH, Pan J. Dynamically Updated B0 Shimming for Multi-band Imaging with High Order Spherical Harmonics, ISMRM 2019 #1473, which is incorporated herein by reference in its entirety). With increasing MB factor, the improvement over static shimming dissipates. Notably, SH shimming significantly outperforms a 32-channel MC coil. Described below are the underlying theory for simultaneous multi-slice shimming, as well as the requisite spatial symmetries of the applied B₀ correction fields needed to maintain the entire gain in B₀ homogeneity, afforded by slice-by-slice shimming for MB=4 imaging. MB=4 imaging is chosen as a target, since for 7T, recommended MB factors for the human connectome lifespan project ranged from 2 to 5 for resting state functional MRI and diffusion tensor imaging, respectively. However, it is expressly contemplated that an MB factor different from 4 may be used. Disclosed herein is a new shim insert which marries the advantages of spherical harmonic-based symmetries with a matrix-based approach to enhance efficiency and performance. While the embodiments disclosed herein are directed to brain imaging, it is expressly contemplated that the claimed invention is not limited to MRI of the brain, but can be applied to MRI imaging of any part of the human body or MRI of animals.

Slice-by-Slice Dynamic Shim Updating (DSU) with SH

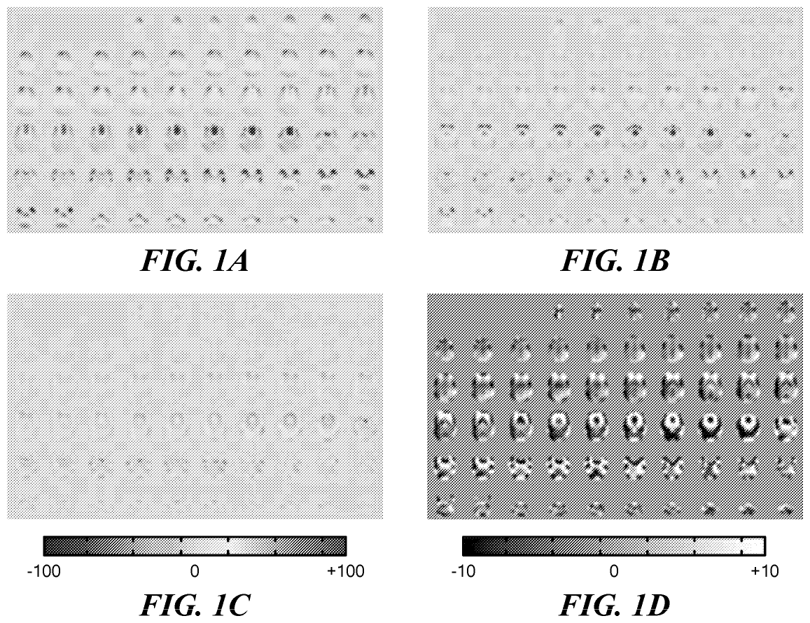

FIG. 1 shows B₀ maps acquired with: FIG. 1A: static 1^{st} & 2^{nd} degree shims; FIG. 1B: static 1^{st}-4th-degree shims; FIG. 1C: dynamically updated slice-by-slice with 1^{st}-4th-degree shims; FIG. 1D: map shown in C with a scale of +/−10 Hz and inverted sign; FIG. 1E: plot of SD of each slice for A, B and C; and FIG. 1F: slice #43 from D.

Displayed in FIG. 1A-C are B₀ maps acquired by spanning the head (114 mm) using static shimming with 1^{st}-2^{nd} and 1^{st}-4th+shims, and dynamic updating with 1^{st}-4th-shims. Displayed in FIG. 1D are plots of B₀ as a function of slice for 1^{st}-2^{nd} order and 1^{st}-4th+degree static shimming, as well as DSU SBS shimming using the 3 slice regions of interest (ROIs). As expected, the DSU SBS approach gives significant gains across the entire brain when compared with static shimming, either static 1^{st}-4th- or 1^{st}-2^{nd} static shimming. FIG. 1D shows the B₀ maps from FIG. 1C re-windowed to span ±10 Hz, with the sign inverted and presented in gray scale. As can be seen from the superior 40% of slices, the residual inhomogeneity is largely dominated by intrinsic gray and white matter differences. This is reflected in the measured σB₀. FIG. 1D, which approaches the 4-5 Hz difference in gray and white matter susceptibility at 7T. For eight subjects, the mean and standard deviation for the whole brain (all brain pixels included in the ROIs across all slices) was 32.7±2.4, 24.5±2.6 and 14.8±1.5 for 1^{st} & 2^{nd} static, 1^{st}-4th±static, and 1^{st}-4th±SBS.

### Spherical Harmonics and Shim Degeneracy

Given a thin, single z-slice target, it is pertinent to consider the spherical harmonic functions for their z-dependencies. Under these conditions, SHs can be divided into two groups, i.e. those with and without a linear z-dependence, here denoted as non-z-degenerate “NzD” (Cn, Sn, Z0, Z2, Z2Cn, Z2Sn . . . )and z-degenerate “zD” respectively (ZCn, ZSn, Z, Z3, Z3Cn, Z3Sn . . . ). In this disclosure, spatial coordinates are referred to by lower case letters (e.g. r, x, y, z). For an arbitrarily thin target slice, the optimal correction field is given by Equation 2:

$${B}_{0} ( r ) = {B}_{0} ( x , y , z ) = {a}_{0} Z 0 + {\sum }_{i = 1}^{n} {a}_{i} N z {D}_{i} ( r ) \qquad ( Eq . 2 )$$

The amplitudes of the degenerate terms, zDᵢ, are scaled by both their position along the Z axis and a scaling coefficient relative to their non-degenerate partners, NzDᵢ, as shown in the following equation:

$${zD}_{i} ( x , y ) = {b}_{0} * Z 0 + {b}_{1} z * {NzD}_{i} ( x , y ) \qquad ( Eq . 3 )$$

Thus, MB shimming can be achieved for axial slices by using the combination of NzD and zD terms. For example, a linear combination of X and ZX (NzD and zD respectively) shims can generate two different in-plane pure X gradients at two unique z-offsets. In an exemplary shim insert, with the exception of Z4 and Z2C2 and Z2S2 shims, every NzD has a partner zD shim. Thus, as long as these “unpaired” NzD terms (Z4, Z2S2, Z2C2) have minimal impact on the overall single slice homogeneity, MB=2 shimming of thin axial slices achieves nearly identical results as DSU SBS.

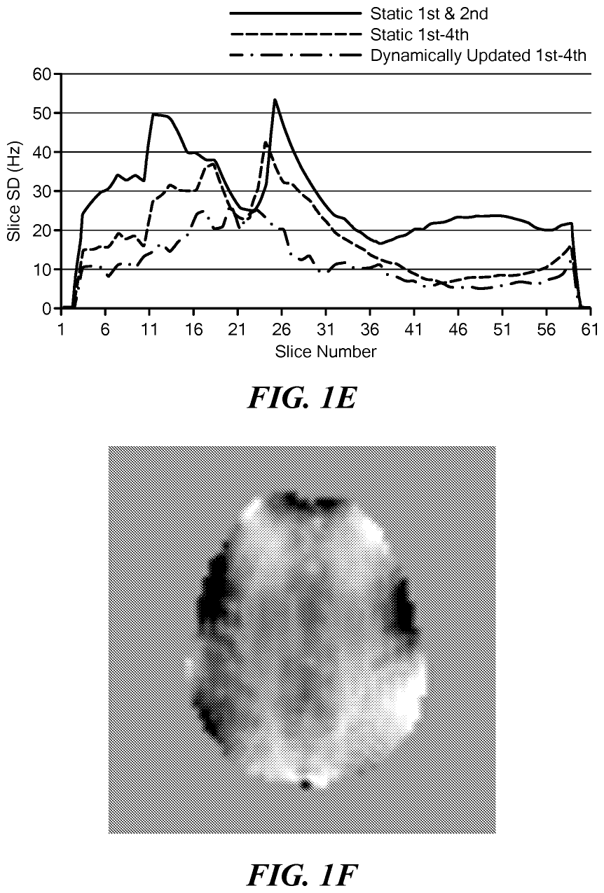

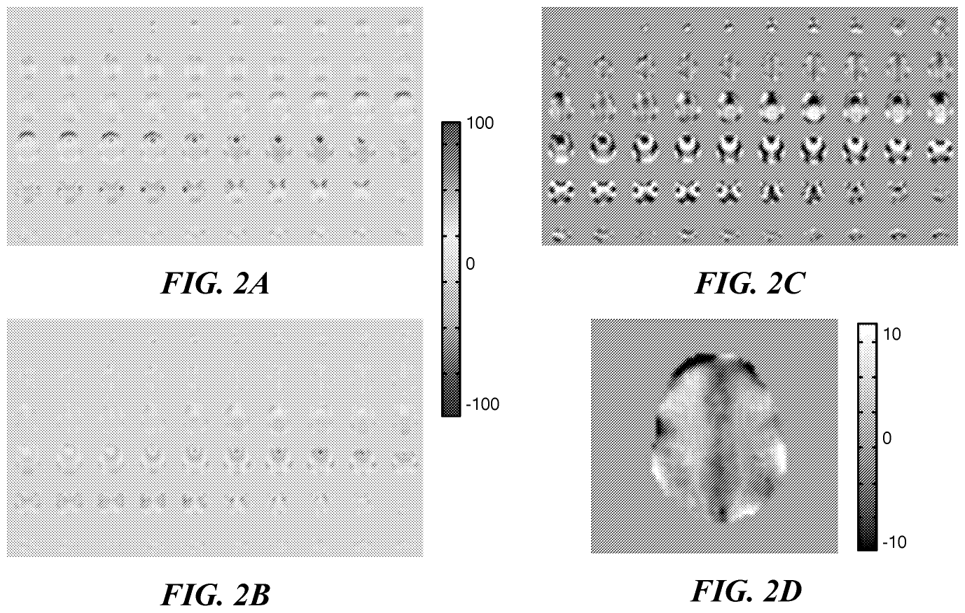

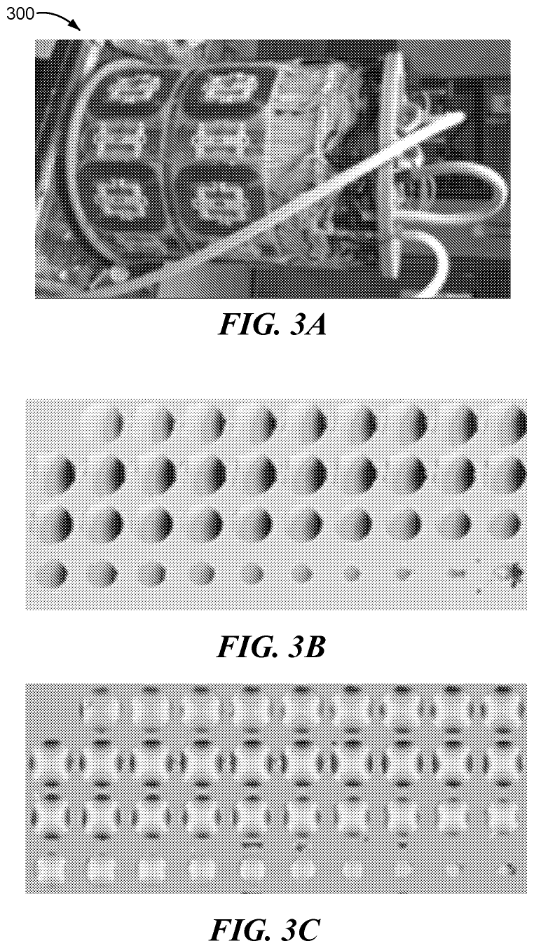

FIG. 2A shows B₀ maps of 58 2 mm slices acquired using static 1^{st}-4th+shims, σB₀=21.3 Hz. FIG. 2B shows B₀ maps of 58 2 mm slices acquired using 1^{st}-4th+dynamic MB=2 shimming, σB₀=13.5 Hz. FIG. 2C shows MB=2, DSU maps, inverted scale+10 Hz for visualization. FIG. 2D shows a single slice map, MB=2 DSU inverted scale+10 Hz, single slice σB₀=4.5 Hz.

Displayed in FIGS. 2 and 2B are B₀ maps, acquired with 1^{st}-4^{th} static and DSU MB=2 shimming. Similar to that seen for slice-by-slice shimming, the achieved B₀ homogeneity over the superior 40% of the brain is primarily limited by the intrinsic susceptibility difference between gray and white matter (FIGS. 2C and 2D). For n=8 subjects, the mean and standard deviation for the whole brain (all brain pixels included in the ROIs across all slices) was 23.4±3.2, 14.6±1.9 for 1^{st}-4th+static and 1^{st}-4th, MB=2, consistent with that measured for the slice-by-slice methods, 14.8±1.5 Hz, as shown in FIG. 1C.

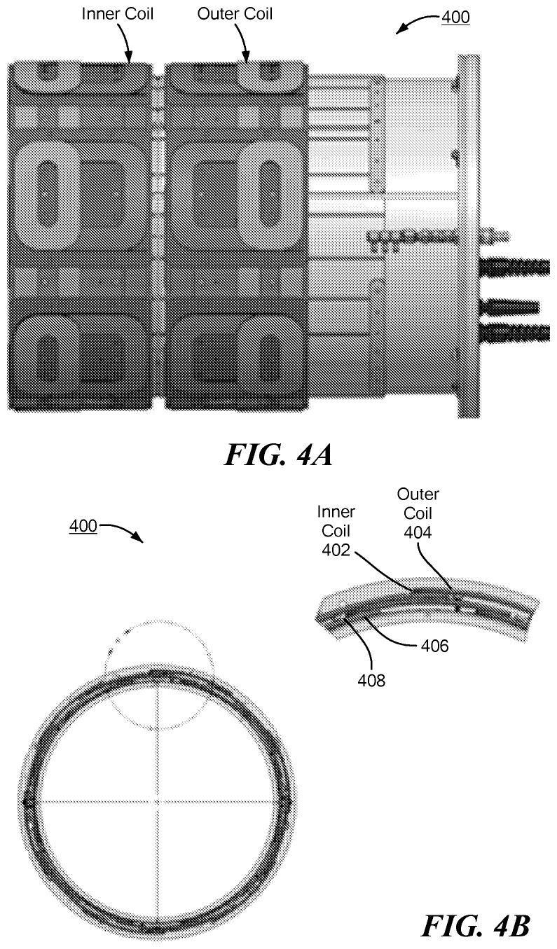

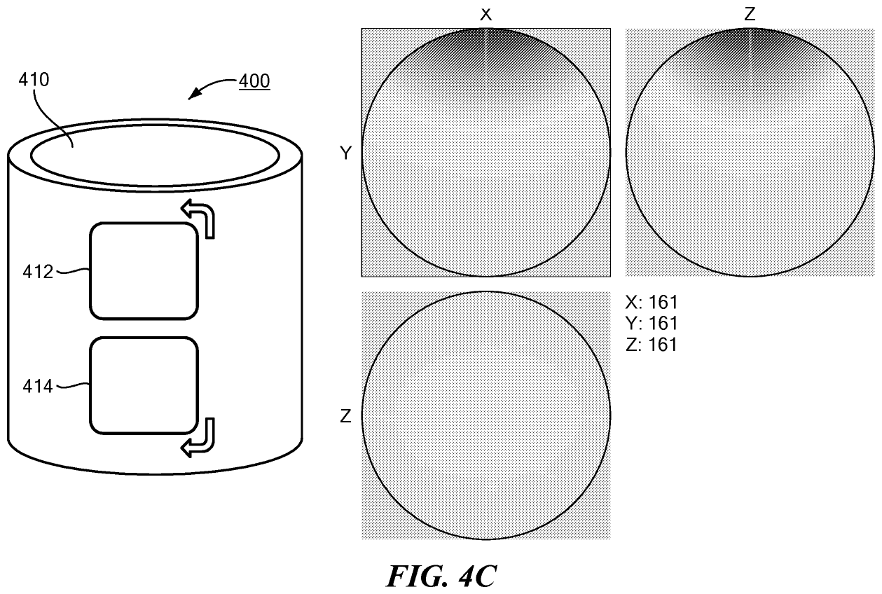

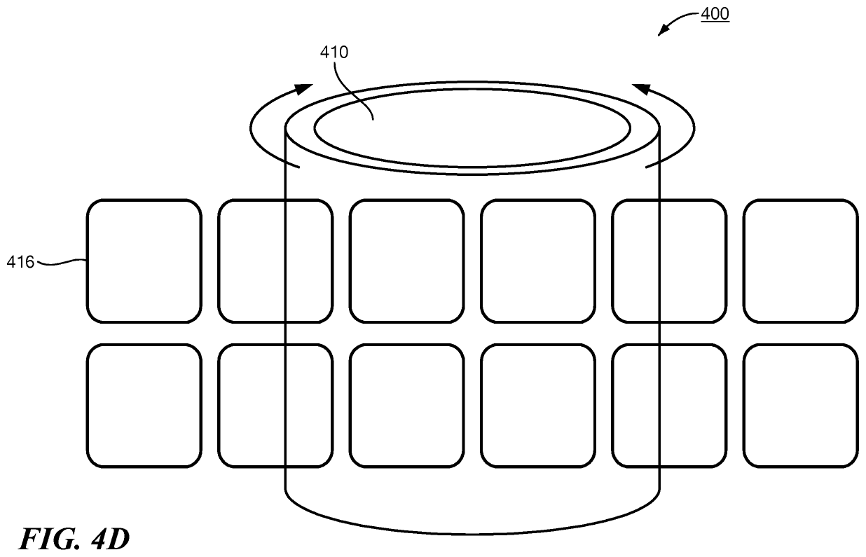

For higher factor MB imaging, e.g. MB=4, it is necessary to achieve the target values at four discrete locations simultaneously, i.e. achieving terms approximating (a₀+a₁z+a₂z²+a₃z³) NzDᵢ. Notably these locations may be widely separated and may depend on the field of view (FOV) of the slices, i.e. FOV_{slice}/MB. Thus, similar to that used to deconvolute aliasing in the slice direction for MB imaging (using rows of receiver arrays), the generation of independent bands of Cn/Sn families of shims along the Z axis of the insert should enable the target values to be reached at the spatially separated (FOV_{slice}/MB) slice locations. A layout of the practical design is shown and described below with reference to FIG. 4A. It illustratively contains four bands of partially overlapping coils with 12 elements, each thus allowing for generation of 6-fold symmetry linear combinations and all subsets (1, 2, 3, 4, and 6), except for five-fold symmetry that can be approximated if required.

### C6/S6 Matrix Array

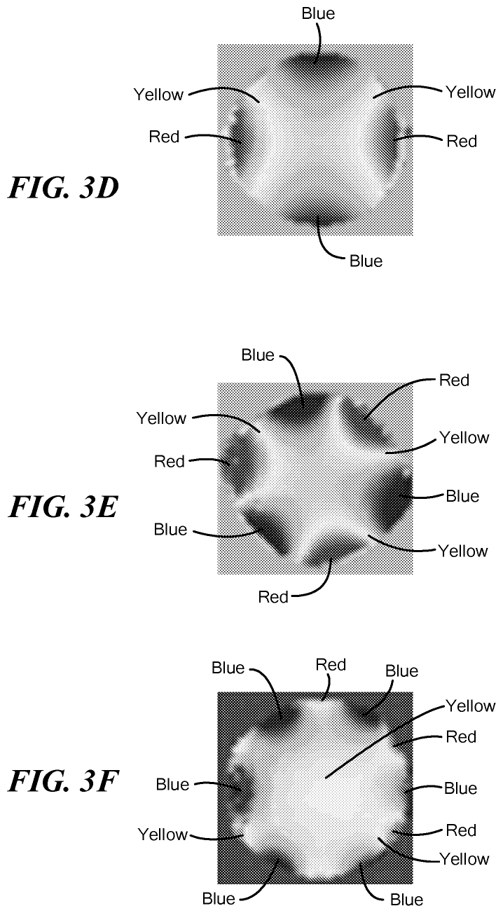

FIG. 3A shows a photograph of an exemplary C6/S6 two-band head shim insert 300 during construction. FIG. 3B shows B₀ maps of a single channel. FIG. 3C shows a B₀ map with currents adjusted to all 48 channels to produce a C2 symmetry. FIG. 3D is a single slice B₀ map of C2 symmetry. FIG. 3E shows B₀ maps of all 48 channels driven to generate a C3 symmetry rotated by 15 degrees. FIG. 3F shows B₀ maps of all 48 channels driven to generate a C6 symmetry (note phantom is slightly offset to the right).

The head shim insert 300 may exemplarily be constructed to provide C and S symmetries up through C6/S6, ZC6/ZS6 along with Z0 and Z2. The data shown in FIGS. 3B-3F was acquired at 7T on a whole body Siemens system using a 50-channel, 5 amp/channel power supply. The head shim insert 300 as shown in FIG. 3A may have 48 individual coils, arranged in two rows of 24 coils each along the Z axis of the insert. Within each row of 24 coils, there are 4 layers of 6 coils. Two partially overlapping layers of 6 coils each are used to form the Cn and Sn families respectively. Displayed in FIGS. 3D-3F are B₀ maps acquired with the matrix array driven to generate C2, C3 and C6 spatial distributions. Notably, the C2, C3, and C6 symmetries generate a maximum B₀ shift of 100 Hz at the edge of 16 cm diameter sphere currents of 0.04, 0.15 and 1.2 amps respectively to each coil, indicating the high efficiency of the advantageous system and method disclosed herein. A higher degree of zonal shims can be synthesized using substantially rectangular coil patterns with multiple bands (e.g. 4).

Systems for dynamic MRI shimming in accordance with various embodiments of the invention may include sets of coils constructed using a combination of techniques. Coils to produce zonal (axially symmetric) shims can be built on a former of approximately 400 mm internal diameter (ID), using rectangular copper wire. Use of the 400 mm bore shim former ensures compatibility with the commercially available transmit/receive RF head coils such as Nova Medical 8TX/32RX or equivalent design. A matrix suitable to generate Z-shims is prone to substantial coupling with the Z1 imaging gradient. It is therefore convenient to retain the serial design technique for this family of shims. Even order symmetry shims (Z0, Z2, Z4 . . . ) can be wound symmetrically about center, while odd order (Z3) require compensation against coupling with the Z1 imaging gradient. A way to decouple the Z1 and Z3 terms can be accomplished with an asymmetric design of 6 solenoidal coils disposed along the z-axis as demonstrated in U.S. Pat. No. 8,536,870 to Punchard et al., which is included herein by reference in its entirety. Only Z0, Z2, Z3 and Z4 are expected to be used in this set, requiring four channels of power amplifiers.

FIG. 4A shows an exemplary shim coil insert 400 in accordance with various embodiments of the invention. Shim coil insert 400 includes an azimuthal set of shims in multiple layers of coils disposed symmetrically around the center of the bore. Two coils are on each side of the centerline in four partially overlapping layers at four locations along Z. The target symmetry is 6-fold, therefore in order to maintain full symmetry control, partially overlapping bands of two sets of 12 coils each need to be present. For the C6 and S6 orthogonal symmetry, each set of 12 coils needs to be offset by ½ pitch, that is 15 degrees.

FIG. 4B shows a cross-sectional view of exemplary shim coil insert 400, illustrating the azimuthal set of shims in multiple layers of coils. For example, two S6 and two C6 coils are shown. Outer coil S6 404 is disposed in a layer above inner coil S6 402. Inner coil S6 402 is disposed in a layer above outer coil C6 408. Outer coil C6 408 is disposed in a layer above inner coil C6 406.

FIGS. 4C, 4D and 4E illustrate exemplary arrangements of the plurality of coils of the shim coil insert 400 in accordance with various embodiments of the invention. In FIG. 4C, Cn Sn type SH terms coils may be arranged in pairs in the head to foot direction. For example, coils 412 and 414 may form such a pair. When driven with current flowing in opposite directions, (i.e. opposite current arrows), the pair of coils 412, 414 creates an extended region of moderately uniform B₀ field in the z direction, as shown on the right of FIG. 4C

FIG. 4D shows an exemplary shim coil insert 400 capable of generating C6/S6 symmetries in accordance with various embodiments of the invention. The circumference of the former with bore 410 is tiled with 6 individual coils 416, with the coils located at 60 degree increments (360/6). More than one ring of coils 416 may be arranged around the bore 410. While FIG. 4D shows two rings of coils, it is expressly contemplated that more rings of coils are disposed along the bore along the Z axis.

, To achieve a higher spatial complexity, more coils are needed. As illustrated in FIG. 4E, an exemplary way to do that is to add additional layers of the same coils and rotating the layers relative to each other. In FIG. 4E, coils 420 is rotated by ½ the pitch of the coils compared to the coils 418, i.e. 60 degree/2=30 degrees. The two layers of coils 418 and 420 may, for example, be configured to generate Cn symmetries up to C6.

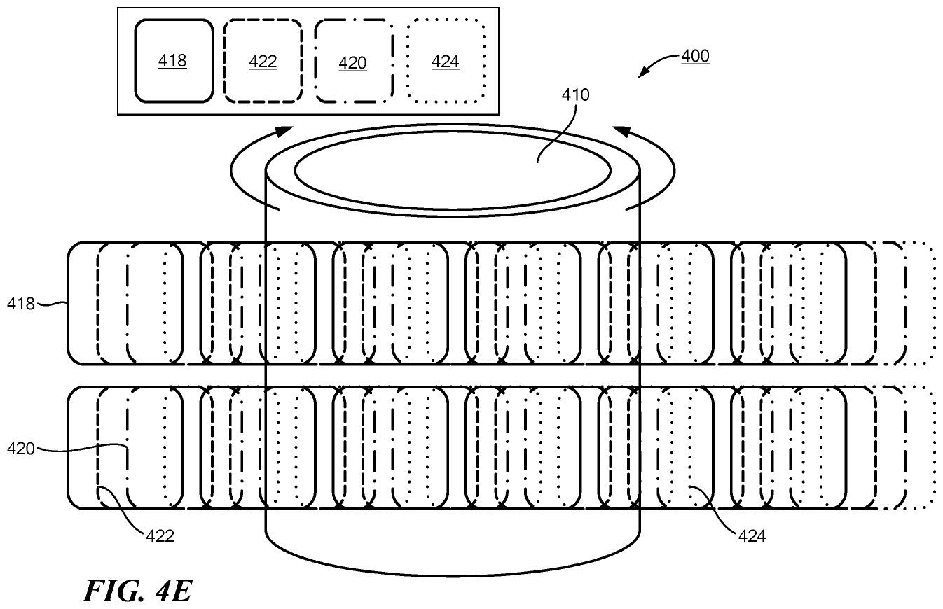

For spherical harmonic shimming, the Sn based symmetries need to be generated in addition to the Cn symmetries. The Cn symmetries are rotated by ½ the pitch of the corresponding Sn symmetry. Thus, for a S3 symmetry C3 symmetry needs to be rotated by 30 degrees. For an S6 symmetry, the C6 symmetry needs to be rotated by 15 degrees. Therefore, to achieve the S6 symmetries, an additional layer of coils to needs to be added to get the finer rotation. These are coils 422 and 424 in FIG. 4E. Layers of coils 422 and 424 may be thought of as the “S” layers. Layers of coils 418, 420, 422, and 424 now include 24 coils in each band offset by 15 degrees from each other. These four layers of coils allow generation of different symmetries by changing the current distributed to each coil. The various coils may be constructed as saddle coils as described below with reference to FIG. 5, or they may be any other coil known to a person having skill in the art.

FIG. 5 shows an exemplary coil 500 in accordance with various embodiments of the invention. The exemplary coil 500 is tightly wound using a substantially rectangular conductor (4:1), AWG18, in a saddle format. This means that the coil 500 is disposed on the bore or shim coil insert like a saddle. With line 506 indicating the Z axis of the bore or shim coil insert, the coil 500 includes two arcs 502 and 504. While a saddle coil is disclosed herein, it is expressly contemplated that different coils may be used. For example, using printed circuit boards can streamline the construction process. As known to a person skilled in the art, circuit resistance, packing density, and self-resonance must be considered in order to arrive at the most cost-effective manufacturing method.

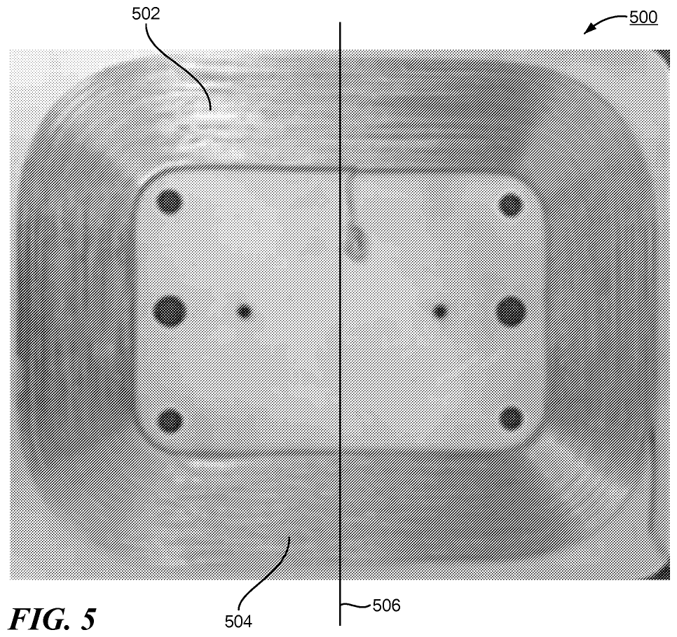

FIG. 6 shows two different shades of blocks that are coil winding cross-sections representing the arcs of the coils, such as arcs 502 and 504 of exemplary coil 500. With windings powered in opposite current sense generate “odd” symmetry fields. The inner coil is driven at 0.5 A, and the outer coil is driven at 2.5 A. There are three zero crossing points of axial magnetic field Bz along the z-axis over the FOV.

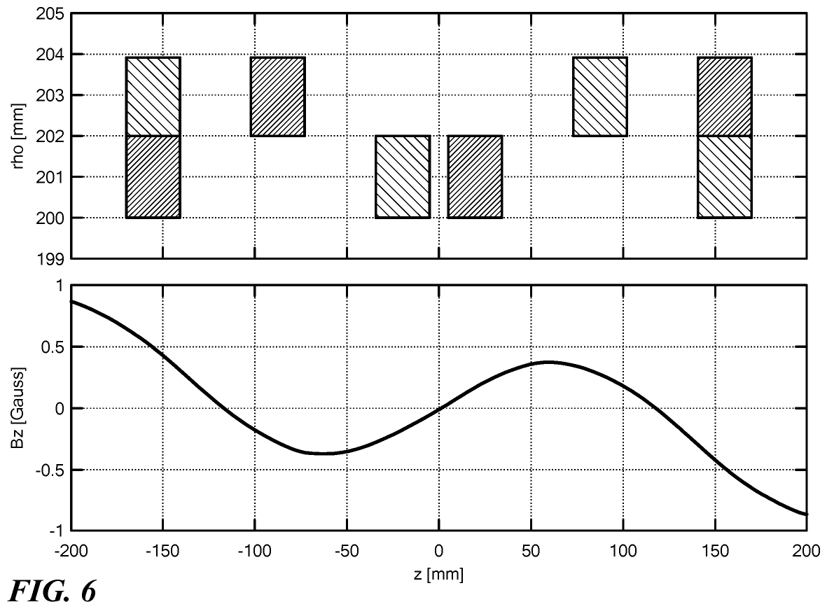

Within each band of coils, windings can be powered in desired current and polarity to generate the correct periodicity, while the current sense between bands can generate “even” or “odd” symmetry zonal fields. Adjusting the current in individual coils can create the required degree of complexity in any of the harmonic orders. A combination of resulting shims is merely an arithmetic sum of all the currents in a given set of circuits, as shown in FIG. 7 below. For example, the use of four bands can create a function of up to third degree (Z3) or below. FIG. 6 shows such behavior where there are three zero crossing points of axial magnetic field Bz along the z-axis over the FOV. This can generate Z3Cn symmetry shims in all orders from n=1 to n=6 (except n=5).

FIG. 7 shows an example of how to combine the currents in a given set of circuits to achieve a desired symmetry in accordance with various embodiments of the invention. More specifically, the example shown is applicable to a shim coil insert as shown in FIG. 4D. The exemplary shim coil insert has four layers of six coils each arranged in two rows. As shown in FIG. 4D, the four layers may be called the black 418, blue 420, red 422, and green layers 424. FIG. 7 illustrates how to drive the six coils #1-#6 in each one of the four layers to generated C6 and S6 symmetries, respectively. When each coil is driven with the indicated current and indicated polarity, the desired symmetry or magnetic field term can be achieved. It is to be noted that not all coils may be driven for a given symmetry. For example, the upper red and green layers may not be driven at all, or in other words driven with a current of zero, to achieve C6 symmetry. While only relative currents of 0, 1, and −1 are shown in FIG. 7, it is expressly contemplated that any number could be used to indicate relative or absolute current.

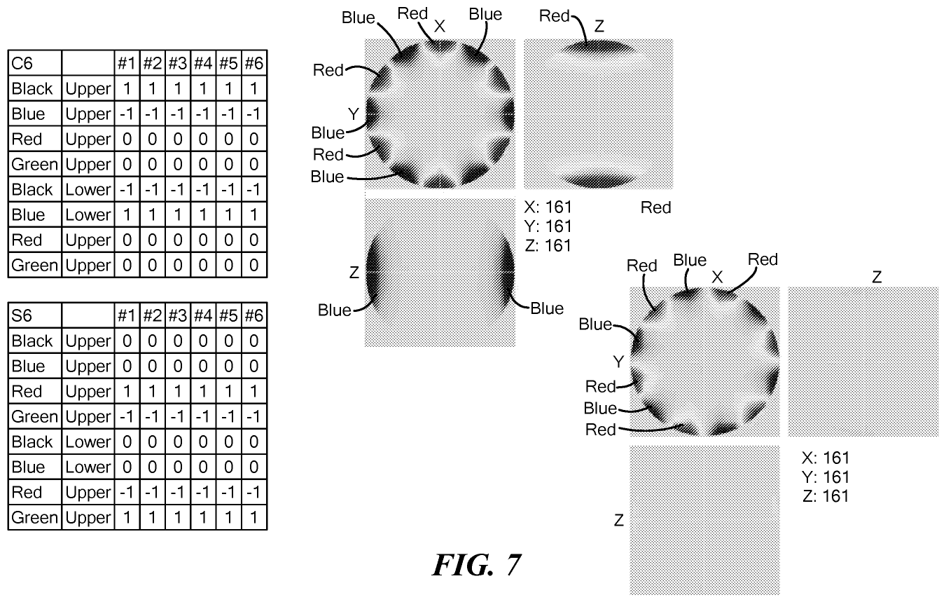

FIG. 8 is a block diagram of an exemplary system 800 for dynamic MRI shimming in accordance with various embodiments of the present disclosure. A controller 902 is electrically coupled to a plurality of shim coils 904. The shim coils 904 may, for example, be a plurality of coils constructed and arranged as described in detail above. The construction of the system 800 may be modular and illustratively may be based on 8-channel banks, each with its own controller 802 for supervision and programming. The controller 802 is also electrically coupled to a power source 806, which may exemplarily be a 50-channel DC power source. Due to the modular construction, a set of 12 banks is sufficient to power the radial coil matrix of 96 channels and one partial bank of 4 channels to drive the axial set of serial shim coils. In the embodiment illustrated herein, a total of 100 channels is required. However, it is expressly contemplated that the system 800 includes less or more than 100 channels.

Illustratively, the controller 802 may store about 1000 values for each channel with synchronous buffering of digitally programmable levels of shims. An external trigger generated from the scanner pulse programmer can load all channels with individual values or strings resulting in smooth profiles. The use of smooth ramp profiles is useful to avoid excessive Eddy currents.

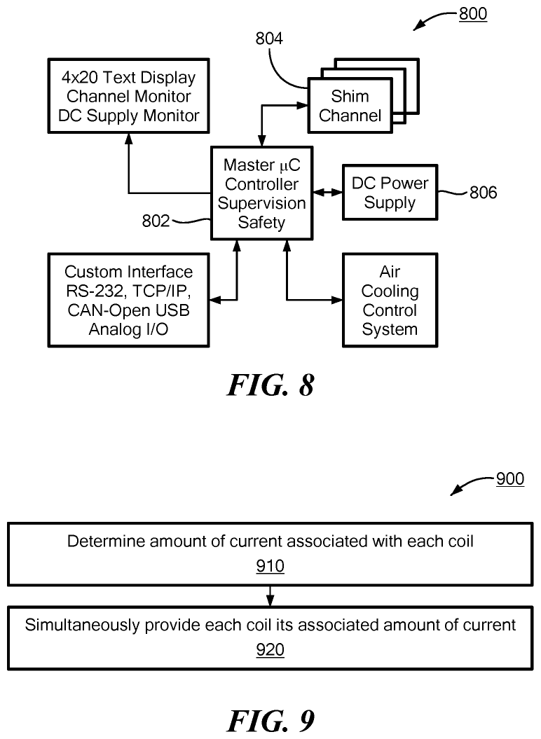

FIG. 9 is a flowchart of a method 900 for dynamic MRI shimming in accordance with various embodiments of the present disclosure. The method 900 includes processes that may be carried out by a controller, for example the controller 802 of system 800. The controller may be electrically coupled to a plurality of shim coils. The shim coils may be positioned around a bore of an MRI system and may form a shim coil matrix.

In process 910, the controller determines an amount of current associated with each coil of the plurality of coils. The amounts of current are determined so as to obtain a desired magnetic field term. The desired magnetic field term may be conveniently expressed as a set of spherical harmonic terms, each spherical harmonic term having an order. However, it is to be understood that the desired magnetic field term is not limited to a set spherical harmonics terms but may be any magnetic field term known to a person having skill in the art.

In process 920, the controller provides each coil of the plurality of coils its associated amount of current. For example, the controller 802 may route the output of a specific channel of power source 806 to a specific coil of the plurality of coils 804. The controller 802 may also limit the current provided by the specific channel, or it may invert the polarity of the current.

Embodiments of the present invention may be embodied in many different forms, including, but in no way limited to, computer program logic for use with a processor (e.g., a microprocessor, microcontroller, digital signal processor, or general purpose computer), programmable logic for use with a programmable logic device (e.g., a Field Programmable Gate Array (FPGA) or other PLD), discrete components, integrated circuitry (e.g., an Application Specific Integrated Circuit (ASIC)), or any other means including any combination thereof.

Computer program logic implementing all or part of the functionality previously described herein may be embodied in various forms, including, but in no way limited to, a source code form, a computer executable form, and various intermediate forms (e.g., forms generated by an assembler, compiler, networker, or locator.) Source code may include a series of computer program instructions implemented in any of various programming languages (e.g., an object code, an assembly language, or a high-level language such as Fortran, C, C++, JAVA, or HTML) for use with various operating systems or operating environments. The source code may define and use various data structures and communication messages. The source code may be in a computer executable form (e.g., via an interpreter), or the source code may be converted (e.g., via a translator, assembler, or compiler) into a computer executable form.

The computer program may be fixed in any form (e.g., source code form, computer executable form, or an intermediate form) either permanently or transitorily in a tangible storage medium, such as a semiconductor memory device (e.g., a RAM, ROM, PROM, EEPROM, or Flash-Programmable RAM), a magnetic memory device (e.g., a diskette or fixed disk), an optical memory device (e.g., a CD-ROM), a PC card (e.g., PCMCIA card), or other memory device. The computer program may be fixed in any form in a signal that is transmittable to a computer using any of various communication technologies, including, but in no way limited to, analog technologies, digital technologies, optical technologies, wireless technologies, networking technologies, and internetworking technologies. The computer program may be distributed in any form as a removable storage medium with accompanying printed or electronic documentation (e.g., shrink wrapped software or a magnetic tape), preloaded with a computer system (e.g., on system ROM or fixed disk), or distributed from a server or electronic bulletin board over the communication system (e.g., the Internet or World Wide Web).

Hardware logic (including programmable logic for use with a programmable logic device) implementing all or part of the functionality previously described herein may be designed using traditional manual methods, or may be designed, captured, simulated, or documented electronically using various tools, such as Computer Aided Design (CAD), a hardware description language (e.g., VHDL or AHDL), or a PLD programming language (e.g., PALASM, ABEL, or CUPL).

The embodiments of the invention described above are intended to be merely exemplary; numerous variations and modifications will be apparent to those skilled in the art. All such variations and modifications are intended to be within the scope of the present invention as defined in any appended claims.

What is claimed is:

1. A method of shimming an MRI system, the MRI system having a bore and a plurality of coils positioned around the bore, the plurality of coils forming a shim coil matrix, the method comprising:
determining an amount of current associated with each coil of the plurality of coils, so as to obtain a desired magnetic field, wherein the desired magnetic field is expressed as a set of spherical harmonic terms, each spherical harmonic term having an order; and
simultaneously providing each coil of the plurality of coils its associated amount of current,
wherein at least one coil of the plurality of coils is configured to contribute to a plurality of spherical harmonic terms having different orders.

2. The method of claim 1, wherein each spherical harmonic term has an order selected from the group consisting of 1, 2, 3, 4, 5 and 6.

3. The method of claim 1, wherein the amount of current associated with at least one coil is non-zero.

4. An MRI shim coil system comprising:
a plurality of shim coils distributed around a bore of an MRI system, the shim coils distributed around the bore so that applying an amount of current associated with each coil of the plurality of coils produces a desired magnetic field, wherein the magnetic field is expressed as a set of spherical harmonic terms, each spherical harmonic term having an order,
wherein the amount of current associated with at least one coil is different from the amount of current associated with another coil; and
wherein at least one coil of the plurality of coils is configured to contribute to a plurality of spherical harmonic terms having different orders.

5. The MRI shim coil system of claim 4, wherein each spherical harmonic term has an order selected from the group consisting of 1, 2, 3, 4, 5 and 6.

6. The MRI shim coil system of claim 4, wherein the amount of current associated with at least one coil is non-zero.

7. The MRI shim coil system of claim 4, wherein each one of the plurality of coils includes a set of arc portions, and wherein at least one arc portion of at least one coil is arranged so that it partially overlaps with an arc portion of another coil.

8. The MRI shim coil system of claim 4, wherein the plurality of coils includes 24 coils and integer multiples thereof.

9. The MRI shim coil system of claim 4, wherein each coil of the plurality of coils is substantially rectangular in shape.

10. The MRI shim coil system of claim 4, wherein the plurality of coils includes 48 coils arranged in four layers.

11. An MRI shim coil system comprising:
a plurality of shim coils distributed around a bore of an MRI system; and
a controller, electrically coupled to the plurality of shim coils and configured to:
determine an amount of current associated with each coil of the plurality of coils, so as to obtain a desired magnetic field, wherein the desired magnetic field is expressed as a set of spherical harmonic terms, each spherical harmonic term having an order; and
simultaneously provide each coil of the plurality of coils its associated amount of current,
wherein at least one coil of the plurality of coils is configured to contribute to a plurality of spherical harmonic terms having different orders.

12. The MRI shim coil system of claim 11, wherein each spherical harmonic term has an order selected from the group consisting of 1, 2, 3, 4, 5 and 6.

13. The MRI shim coil system of claim 11, wherein the amount of current associated with at least one coil is non-zero.

14. The MRI shim coil system of claim 11, wherein each one of the plurality of coils includes a set of arc portions, and wherein at least one arc portion of at least one coil is arranged so that it partially overlaps with an arc portion of another coil.

15. The MRI shim coil system of claim 11, wherein the plurality of coils includes 24 coils and integer multiples thereof.

16. The MRI shim coil system of claim 4, wherein each coil of the plurality of coils is substantially rectangular in shape.

17. The MRI shim coil system of claim 11, wherein the plurality of coils includes 48 coils arranged in four layers.
